(19) United States
(12) Patent Application Publication
(10) Pub. No.: US 2009/0310687 A1
(43) Pub. Date: Dec. 17, 2009

(54) METHOD AND APPARATUS FOR SPACE-TIME-FREQUENCY ENCODING AND DECODING

(75) Inventors: Gang Wu, Shanghai (CN); Timothy James Moulsley, Caterham (GB); Xun Fan, Shanghai (CN); Ni Ma, Shanghai (CN); Qi Zhou, Shanghai (CN); Xiaobo Zhang, Shanghai (CN)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/374,412

(22) PCT Filed: Jul. 11, 2007
(86) PCT No.: PCT/IB07/52759

§ 371 Date: Jan. 20, 2009

(30) Foreign Application Priority Data
Jul. 21, 2006 (CN) 200610105987.9

(51) Int. Cl. H04B 14/04; H04L 27/00; H03K 9/00

(52) U.S. Cl. 375/242; 375/295; 375/316

(57) ABSTRACT

The present invention provides a space-time-frequency encoding and decoding method and apparatus used in a wireless communication system. With the encoding method provided in the invention, transmission code words and their redundant elements are properly allocated on space-time-frequency units, so that the transmission codes and their partial redundancies can be transmitted via different antennas. Accordingly, at the receiving side, the redundant elements and the corresponding code word elements can be combined, so as to enhance the SNR and diversity gains for a part of the elements in the code words, and hence enhance the reception quality for the overall data stream.

### FIELD OF THE INVENTION

The present invention relates generally to a wireless communication system, and more particularly, to a method and apparatus for space-time-frequency diversity encoding and decoding in a multi-carrier wireless communication system.

### BACKGROUND OF THE INVENTION

It's of great importance to overcome wireless channel fading and channel interference in order to provide high quality data service for users in a wireless communication system. In recent years, STBC (Space-Time Block Coding), with which a space-time transmission diversity gain can be obtained, has been accepted widely in the industry due to its simple encoding and decoding characteristics, and has been chosen as one of the transmission diversity schemes in 3GPP UMTS. The STBC scheme can also be used for an OFDM (Orthogonal Frequency Division Multiplexing) system, that is, an OFDM system employing STBC. In the case that block coding is performed in the space-frequency domain instead of the space-time domain, an OFDM system employing SFBC (Space-Frequency Block Coding) is implemented.

A method for implementing transmission diversity with a plurality of antennas in a multi-carrier communication system is disclosed in a patent application with publication No. WO2004/073275A1 published on Aug. 26, 2004, entitled “Space-Time-Frequency Diversity for Multi-carrier Systems”. According to the method disclosed in this patent application, firstly, a set of transmission symbols is converted according to a predetermined rule, to generate a plurality of transmission streams; then, transmission elements in each of the transmission streams are allocated to time-frequency units associated with the antennas and corresponding to a plurality of carriers and symbol intervals, and transmitted via corresponding antennas. This method achieves a space-time-frequency orthogonality through an orthogonal design. Since the space-time coding and space-frequency coding in this scheme are independent of each other, the transmission diversity gain obtained through coding is one dimensional space-time diversity gain or space-frequency diversity gain.

Therefore, there is a need for a more effective encoding method, in order to further enhance the data transmission quality.

### SUMMARY OF THE INVENTION

The technical problem to be solved in the present invention is to provide an effective encoding method, in order to enhance the data transmission quality.

For this purpose, the present invention provides a space-time-frequency encoding method. The method according to the invention comprises steps of: coding a set of transmission symbols according to a predetermined orthogonal STBC rule, so as to obtain a plurality of code words; and mapping a plurality of elements in each of the plurality of code words and redundancy for at least part of the plurality of elements, as channel elements, to a plurality of predetermined time-frequency units in one of a plurality of two dimensional time-frequency matrixes corresponding to the code word, so that the channel elements in each of the matrixes can be transmitted via an antenna corresponding to the matrix.

In an embodiment, the predetermined orthogonal STBC rule is an Alamouti STBC for two transmitting antennas.

In another embodiment, the predetermined orthogonal STBC rule is an extended Alamouti STBC for three or four transmitting antennas.

The present invention also provides a decoding method corresponding to above encoding method. The decoding method according to the invention comprises steps of: extracting a plurality of sets of faded channel elements corresponding to a set of transmission symbols among a plurality of signal streams received from different transmitting antennas, wherein each of the sets of channel elements includes code word elements and at least partial redundancies thereof; combining the redundant channel elements and the code word elements corresponding to the redundant channel element in each of the sets of channel elements, so as to obtain a transmission code word composed of the channel elements that are obtained through the combination and the remaining code word elements in the set of channel elements; and performing a linear combination on a plurality of transmission code words according to a predetermined orthogonal STBD (Space-Time Block Decoding) rule, so as to recover a set of transmission symbols.

In an embodiment, the predetermined orthogonal STBD rule is an Alamouti STBD rule for two transmitting antennas.

In another embodiment, the predetermined orthogonal STBD rule is an extended Alamouti STBD rule for three or four transmitting antennas.

Another technical problem to be solved in the invention is to provide an effective encoding apparatus, which could enhance the gain of data transmission diversity.

For this purpose, the present invention provides a space-time-frequency encoding apparatus, comprising: a coding unit configured to code a set of transmission symbols according to a predetermined orthogonal STBC rule, so as to obtain a plurality of corresponding code words; and a mapping unit configured to map a plurality of elements in each of the plurality of code words and at least partial redundancies thereof, as channel elements, to a plurality of predetermined time-frequency units in one of a plurality of two dimensional time-frequency matrixes corresponding to the code word, so that the channel elements in each of the matrixes can be transmitted via an antenna corresponding to the matrix; wherein the predetermined orthogonal STBC rule is one of an Alamouti STBC rule for two transmitting antennas, an extended Alamouti STBC rule for three transmitting antennas, and an extended Alamouti STBC rule for four transmitting antennas.

Furthermore, the present invention also provides a decoding apparatus, comprising: an extracting unit configured to extract a plurality of sets of faded channel elements corresponding to a set of transmission symbols among a plurality of signal streams received from different transmitting antennas, wherein each the sets of channel elements includes code word elements and redundant elements for at least part of the code word elements; a combination unit configured to combine the redundant channel elements and the code word elements corresponding to the redundant channel elements in each of the sets of channel elements, so as to obtain a transmission code word composed of the channel elements that are obtained through the combination and the remaining code word elements in this set of channel elements; and a decoding unit configured to perform a linear combination on a plurality of transmission code words according to a predetermined orthogonal STBD rule, so as to recover a set of transmission symbols; wherein the predetermined orthogonal STBD rule is one of an Alamouti STBD rule for two transmitting antennas, an extended Alamouti STBD rule for three transmitting antennas, and an extended Alamouti STBD rule for four transmitting antennas.

In the encoding method provided in the invention, through properly allocating transmission code words and their redundant elements to space-time-frequency unit, the transmission code words and their partial redundancies can be transmitted via different antennas. Accordingly at the receiving side, the redundant elements and the code word elements corresponding to the redundant elements can be combined, so as to enhance the SNR (signal-to-noise ratio) and diversity gains for a part of the elements in the code words. Meanwhile, the space-time orthogonal coding design and the space-frequency orthogonal coding design have a similar orthogonal structure with a conventional STBC. At the receiving side, a conventional linear combination can be performed on code words after the combinations of redundant elements and corresponding code word elements, so as to recover the corresponding transmission symbols or symbol blocks. This makes the decoding process quite simple.

Other aspects and attainments together with a fuller understanding of the invention will become apparent and appreciated by referring to the following descriptions and claims taken in conjunction with the accompanying drawings.

### BRIEF DESCRIPTION OF THE DRAWINGS

FIG. 1 is a flowchart illustrating an encoding method according to the invention;

FIGS. 2 (a), (b), and (c) are diagrams illustrating an Alamouti STBC mode for two transmitting antennas, extended Alamouti STBC modes for three and four transmitting antennas respectively;

FIGS. 3 (a), (b), and (c) are diagrams illustrating how to map elements in each of the code words and partial redundancy thereof into time-frequency matrixes as channel elements according to a first embodiment of the invention;

FIG. 4 shows diagrams illustrating how to map elements in each of the code words and partial redundancy thereof into time-frequency matrixes as channel elements according to a second embodiment of the invention;

FIG. 5 shows diagrams illustrating mapping elements in each of the code words and partial redundancy thereof into time-frequency matrixes as channel elements according to a third embodiment of the invention;

FIG. 6 is a flowchart illustrating a decoding method according to the invention;

FIG. 7 is a block illustrating illustrates an encoding apparatus according to the invention;

FIG. 8 is a block diagram illustrating a decoding apparatus according to the invention; and

FIG. 9 is a block diagram illustrating an embodiment of a communication system comprising the encoding apparatus and decoding apparatus provided in the invention.

Throughout all the above drawings, like reference numerals will be understand to refer to similar or corresponding features or functions.

### DETAILED DESCRIPTION OF THE INVENTION

A detailed description will be made below to the encoding and decoding methods and apparatuses provided in the invention in conjunction with the appended drawings.

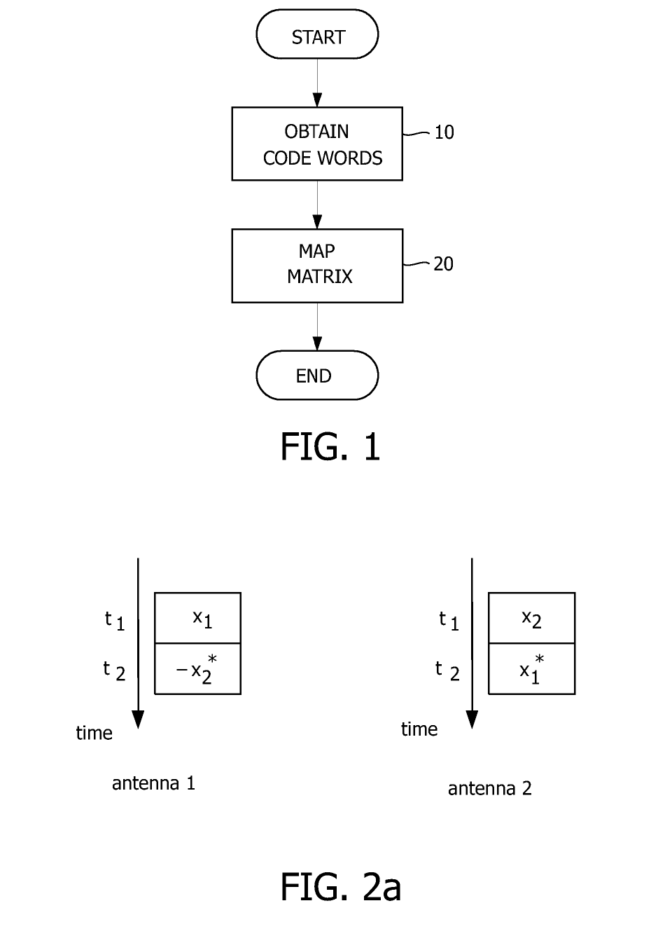

FIG. 1 is a flowchart illustrating an encoding method according to the invention. According to the method provided in the invention, at the transmitting side, a set of transmission symbols is coded according to a predetermined orthogonal STBC rule, so as to generate a plurality of code words (step S10). Then, a plurality of elements in each of the code words and redundant elements for at least part of the elements are mapped, as channel elements, to a plurality of predetermined time-frequency units in one of a plurality of two dimensional time-frequency matrixes corresponding to that code word, so that the channel elements in each of the matrixes can be transmitted via an antenna corresponding to that matrix (step S20).

The orthogonal STBC rule employed in step S10 will vary with the number of transmitting antennas, and the basic principle is to ensure the orthogonality between respective code words through coding. Assuming that N_{I} is the number of input symbols, N_{T} is the number of the transmitting antennas corresponding to the code words obtained through coding, P is the number of elements in one of the code words obtained through coding. Coding modes are somewhat different for different parameters N_{I}, N_{T}, and P, and can be summarized in the following table 1:

TABLE 1
coding modes for different parameters

| A-STBC | B_{3′} STBC | B_{4′} STBC |
|---|---|---|
| N_{I} = N_{T} = P = 2 | N_{I} = 3, N_{T} = 3, P = 4 | N_{I} = 3, N_{T} = 4, P = 4 |

Where A-STBC represents an Alamouti STBC mode for two transmitting antennas, B_{3′}-STBC represents an extended Alamouti STBC mode for three transmitting antennas, and B_{4′}-STBC represents an extended Alamouti STBC mode for four transmitting antennas.

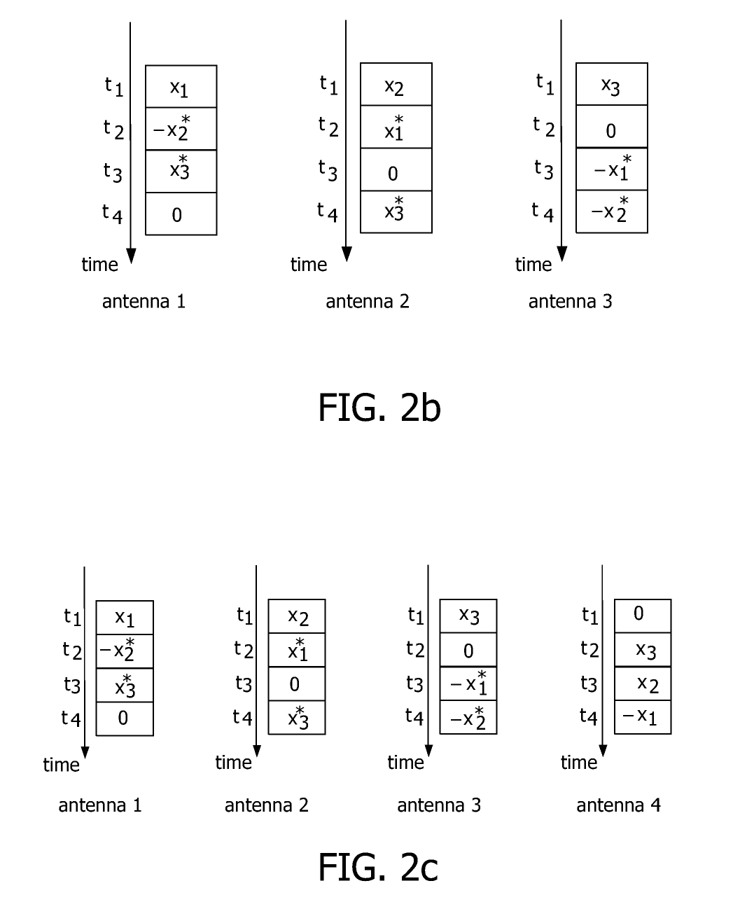

FIGS. 2 (a), (b), and (c) show specific embodiments for the above A-STBC, B_{3′}-STBC, and B_{4′}-STBC coding rules respectively which is described below in detail in connection with the drawings.

In the Alamouti STBC mode shown in FIG. 2 (a), {x₁, x_{2}} as the input symbols or the symbol block are encoded into output code words {x₁, −x₂*} and {x₂, x₁*}, which are orthogonal mutually and can be transmitted via two transmitting antennas respectively. In terms of the coding principle, please refer to the reference document: “A simple transmit diversity technique for wireless communications,” by S. Alamouti, IEEE J. Select. Areas Commun., vol.16, pp.1451-1458, October, 1998.

In the extended Alamouti STBC mode B₃^{′}-STBC shown in FIG. 2 (b), {x₁, x₂, x₃} as the input symbols or the symbol block are coded into output code words {x₁, −x₂*, x₃*, 0}, {x₂, x₁*, 0, x₃*}, and {x₃, 0, −x₁*, −x₂*}, which are orthogonal mutually and can be transmitted via three transmitting antennas respectively. In the extended Alamouti STBC mode B₄^{′}-STBC shown in FIG. 2 (c), {x₁, x₂, x_{3}} as the input symbols or the symbol block are encoded into output code words {x₁, −x₂*, x₃*, 0}, {x₂, x₁*, 0, x₃*}, {x₃, 0, −x₁*, −x₂*}, and {0, x₃, x₂, −x₁}, which are orthogonal mutually and can be transmitted via four transmitting antennas respectively. The coding principles for three or four transmitting antennas can be referred to the document: Space-time block codes from orthogonal designs, by V. Tarokh, H. Jafarkhani, A. R. Calderbank, IEEE Trans. on Info Theory, vol.45, (1999) 5, 1456-1467.

In step S20, the elements in each of the obtained code words obtained in step S10 and the partial redundancies in that code word are mapped to time-frequency units in one of a plurality of two dimensional time-frequency matrixes as channel elements, in order that the channel elements for each of the code words can be modulated on predetermined sub-carriers and transmitted at predetermined symbol intervals via an antenna corresponding to that matrix in the following process, wherein channel elements in different matrixes correspond to different transmitting antennas.

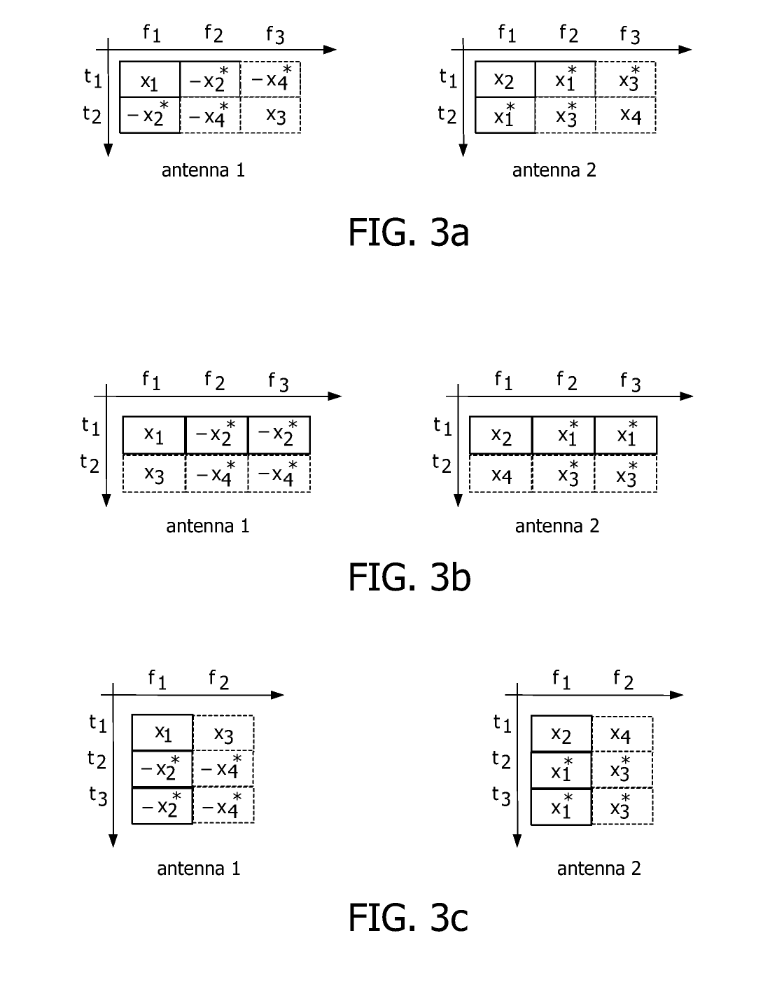

FIGS. 3 (a), (b), and (c) are diagrams illustrating how to map elements in each of the code words and partial redundancy thereof into time-frequency matrixes as channel elements according to a first embodiment of the invention. In the first embodiment corresponding to the A-STBC mode shown in FIG. 2(a), elements in the code words {x₁,−x₂*} and {x₂,x₁*} obtained through coding and the partial redundancies thereof are mapped into two time-frequency matrixes as channel elements. Wherein —x₂* in the first matrix and x₁* in the second matrix are redundant elements, and the channel elements {x₁,−x₂*,−x₂*} and {x₂, x₁*,x₁*} are transmitted via different antennas corresponding to two time-frequency matrixes respectively.

In the description herein and hereafter, in a time-frequency unit {fᵢ, tᵢ} in the matrix, fᵢ denotes a sub-carrier on which channel elements are modulated, and tᵢ denotes a time unit in which channel elements are transmitted and which corresponds to the duration of a symbol.

In the embodiment illustrated in FIG. 3(a), channel elements {x₁,−x₂*,−x₂*} and {x₂,x₁*,x₁*} are transmitted in time-frequency units {t₁,f₁}, {t₁,f₂}, and {t₂,f₁} via antennas 1 and 2 respectively. In the embodiment illustrated in FIG. 3(b), channel elements {x₁,−x₂*,−x₂8} and {x₂,x₁*,x₁*} are transmitted in time-frequency units {t₁,f₁}, {t₁,f₂}, and {t₁,f₃} via antennas 1 and 2 respectively. In the embodiment illustrated in FIG. 3(c), channel elements {x₁,−x₂*,−x₂*} and {x₂,x₁*,x₁*} are transmitted in time-frequency units {t₁,f₁}, {t₂,f₁}, and {t₃,f₁} via antennas 1 and 2 respectively.

In the description above and hereafter, the channel elements shown in the matrixes but not described represent code words obtained through coding other input symbols and the partial redundancies of the code words. Moreover, the time units and frequency units in the matrix can be extended in accordance with the number of sub-carriers and the number of sets of input symbols.

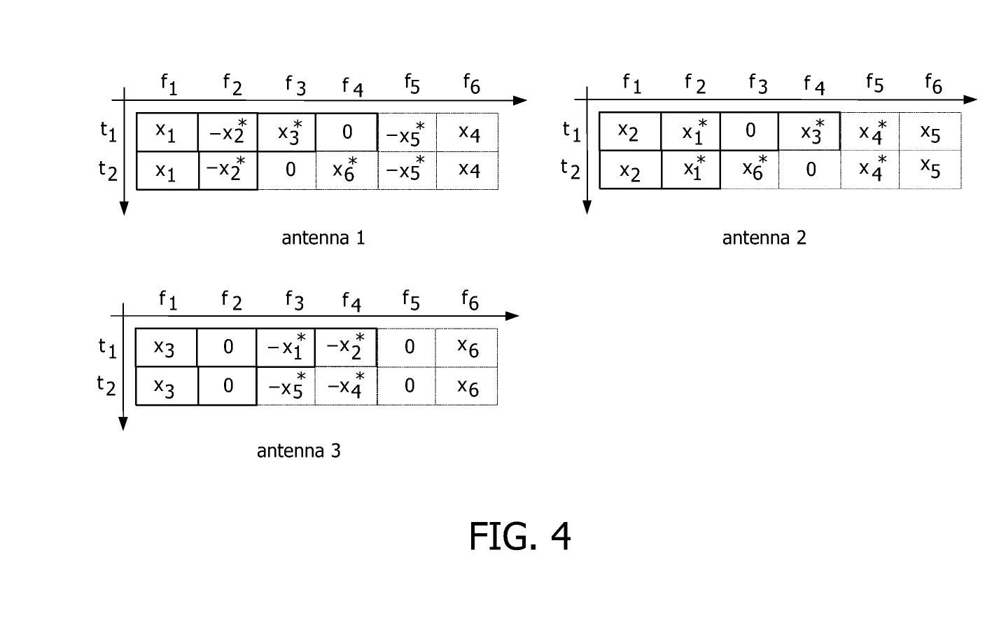

FIG. 4 shows diagrams illustrating how to map elements in each of the code words and partial redundancy thereof into time-frequency matrixes as channel elements according to a second embodiment of the invention. In the second embodiment corresponding to the B₃^{′}-STBC mode shown in FIG. 2(b), elements in the code words {x₁,−x₂*,x₃*,0} {x₂,x₁*,0,x₃*} and {x₃,0,−x₁*,−x₂*} obtained through coding and partial redundancies thereof are mapped into three time-frequency matrixes as channel elements. Wherein {x₁,−x₂*} in the first matrix, {x₂,x₁*} in the second matrix, and {x₃,0} in the third matrix are redundant channel elements.

In the embodiment illustrated in FIG. 4, channel elements {x₁,−x₂*,x₃*,0,x₁,−x₂*}, {x₂,x₁*,0,x₃*,x₂,x₁*}, and {x₃,0,−x₁*,−x₂*,x₃,0} are transmitted in time-frequency units {t₁,f₁}, {t₁,f₂}, {t₁,f₃}, {t₁,f₄}, {t₂,f₁}, and {t₂,f₂} via antennas 1, 2, and 3 respectively. In the description herein and hereafter, channel element {0} represents that no symbol will be transmitted in the corresponding time-frequency unit.

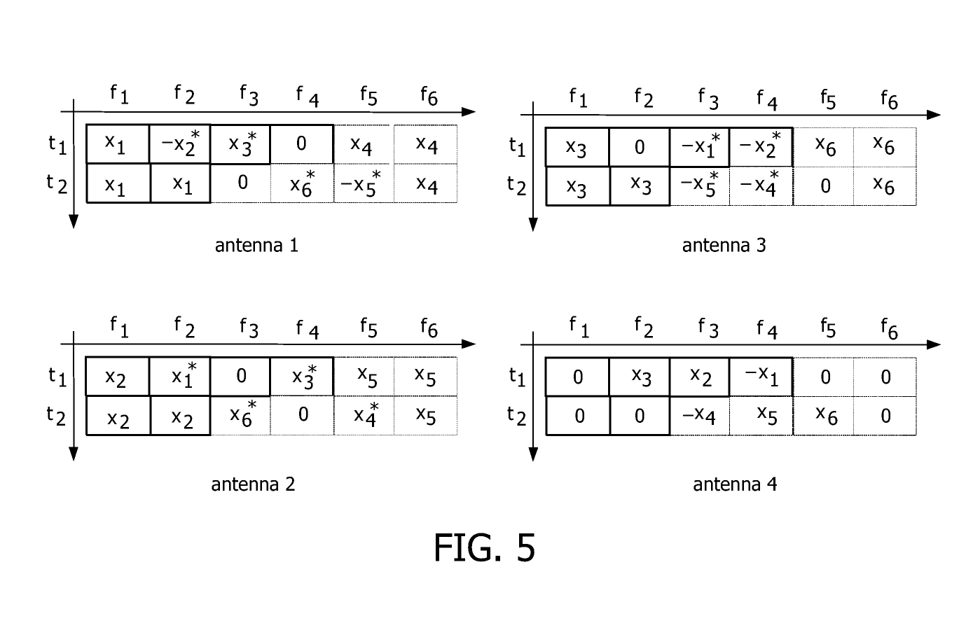

FIG. 5 shows diagrams illustrating mapping elements in each of the code words and partial redundancy thereof into time-frequency matrixes as channel elements according to a third embodiment of the invention. In the second embodiment corresponding to the B₄^{′}-STBC mode shown in FIG. 2(c), elements in the code words {x₁,−x₂*,x₃*,0}, {x₂,x₁*,0,x₃*}, {x₃,0,−x₁*,−x₂*}, and {0,x₃,x₂,−x₁} obtained through coding and the partial redundancies thereof are mapped into four time-frequency matrixes as channel elements. Wherein {x₁} in the first matrix, {x₂} in the second matrix, {x₃} in the third matrix, and {0} in the fourth matrix are redundant channel elements.

In the embodiment illustrated in FIG. 5, channel elements {x₁,−x₂*,x₃*,0,x₁,x₁}, {x₂,x₁*,0,x₃*,x₂,x₂}, {x₃,0,−x₁*,−x₂*,x₃,x₃}, and {0,x₃,x₂,−x₁,0,0} are transmitted in time-frequency units {t₁,f₁}, {t₁,f₂}, {t₁,f₃}, {t₁,f₄}, {t₂,f₁}, and {t₂,f₂} via antennas 1, 2, 3, and 4 respectively.

In the above embodiments, there can be one or more redundant elements and one or more redundant times, which can be adjusted according to the requirement of a practical system.

The encoding method provided in the invention can be used in an OFDM system. In this case, before channel elements are output to a plurality of antennas for transmission, there generally comprises a step of modulating the channel elements in a plurality of time-frequency matrix units on OFDM sub-carriers, and transforming the channel elements on each of the sub-carriers from the frequency domain to the time domain with Fourier Inverse Transformation. While at the receiving side, the channel elements are transformed from the time domain to the frequency domain with Fourier Transformation, and then decoded.

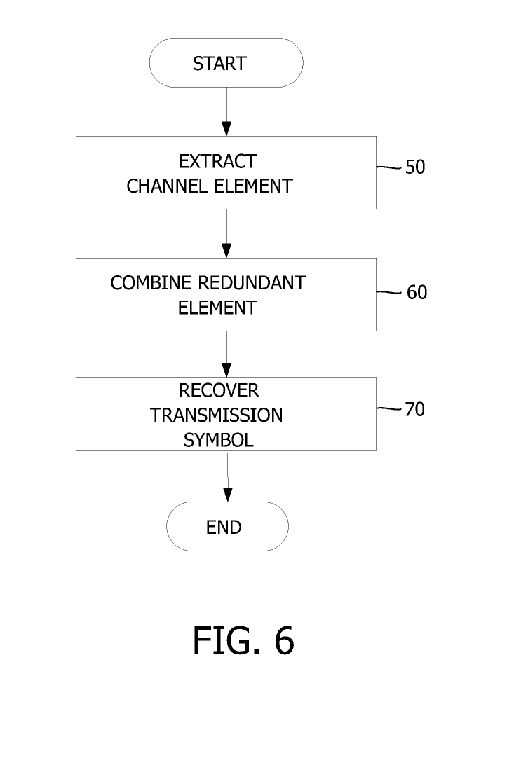

FIG. 6 shows a flowchart illustrating a decoding method according to the invention, which corresponds to the encoding method provided in the invention. In the decoding method provided in the invention, firstly, a plurality of sets of faded channel elements corresponding to a set of transmission symbols are extracted among a plurality of signal streams received from different transmitting antennas, wherein the respective sets of channel elements each include code word elements and at least partial redundant elements thereof (step S50). Next, the redundant channel elements and their corresponding code word elements in each of the sets of channel elements are combined, so that a transmission code word is composed of the channel elements obtained through the combination and the remaining code word elements in this set of channel elements (step S60). Finally, a linear combination is performed on a plurality of transmission code words according to an orthogonal STBD rule, so as to recover a set of transmission symbols (step S70). The decoding method corresponding to B₃^{′}-STBC mode is described in connection with the communication principles and mathematical expressions in details below to provide an explanation for the decoding method provided in the invention and an introduction to advantageous effects thereof.

It is assumed that the input symbols or the symbol block at the transmitting side are {x₁,x₂,x₃}, which are encoded into output code words {x₁,−x₂*,x₃*,0}, {x₂,x₁*,0,x₃*}, and {x₃,0,−x₁*,−x₂*} with B₃^{′}-STBC mode. The elements of each of the code words and the redundancies thereof {x₁,_31 x₂*,x₃*,0,x₁,−x₂*}, {x₂,x₁*,0,x₃*,x₂, x₁*}, and {x₃,0,−x₁*,−x₂*,x₃,0} are mapped, as channel elements, to three time-frequency matrixes as shown in FIG. 4 respectively, and transmitted in time-frequency units {t₁,f₁}, {t₁,f₂}, {t₁,f₃}, {t₁,f₄}, {t₂,f₁}, and {t₂,f₂} via antennas 1, 2, and 3 respectively.

Generally, for conventional wireless communication systems such as 3GPP/WLAN, it can be suitably assumed that the channel response for adjacent symbols and adjacent sub-carriers has time invariant characteristic. While wireless channels undergo deep slow fading, channel elements corresponding to a set of code words transmitted via the same transmitting antenna undergo the same channel response on the wireless channels, that is:

hₘ=[h_{m,1},h_{m,2}, . . . h_{m,N}_{_{R}}]^{T} (1)

where hₘ denotes N_{R} dimensional column vector for the channel response, m=1,2, . . . , N_{T} denotes the sequence number of a transmitting antenna, n=1,2, . . . , N_{R} denotes the sequence number of a receiving antenna, h_{m,n} denotes the channel response that the channel elements transmitted via the m^{th} antenna and received via the n^{th} antenna undergoes in the time-frequency units {t₁,f₁}, {t₁,f₂}, {t₁,f₃}, {t₁,f₄}, {t₂,f₁}, and {t₂,f₂}. A plurality of sets of channel elements corresponding to a set of transmission symbols are extracted among a plurality of signal streams received from different transmitting antennas in step 50, which can be expressed as:

$${[ \begin{matrix}{r}_{{t}_{1} , {f}_{1}}^{T} \\ {r}_{{t}_{1} , {f}_{2}}^{T} \\ {r}_{{t}_{1} , {f}_{3}}^{T} \\ {r}_{{t}_{1} , {f}_{4}}^{T} \\ {r}_{{t}_{2} , {f}_{1}}^{T} \\ {r}_{{t}_{2} , {f}_{2}}^{T}\end{matrix} ]}^{T} = {[ \begin{matrix}{h}_{1}^{T} \\ {h}_{2}^{T} \\ {h}_{3}^{T}\end{matrix} ]}^{T} \cdot [ \begin{matrix}{x}_{1} & - {x}_{2}^{*} & {x}_{3}^{*} & 0 & {x}_{1} & - {x}_{2} \\ {x}_{2} & {x}_{1}^{*} & 0 & {x}_{3}^{*} & {x}_{2} & {x}_{1}^{*} \\ {x}_{3} & 0 & - {x}_{1}^{*} & - {x}_{2}^{*} & {x}_{3} & 0\end{matrix} ] + {[ \begin{matrix}{n}_{{t}_{1} , {f}_{1}}^{T} \\ {n}_{{t}_{1} , {f}_{2}}^{T} \\ {n}_{{t}_{1} , {f}_{3}}^{T} \\ {n}_{{t}_{1} , {f}_{4}}^{T} \\ {n}_{{t}_{2} , {f}_{1}}^{T} \\ {n}_{{t}_{2} , {f}_{2}}^{T}\end{matrix} ]}^{T} \qquad ( 2 )$$

where r_{t,f} denotes N_{R} dimensional column vector extracted from received signal streams, wherein the N_{R} dimensional column vector corresponds to channel elements transmitted in time-frequency unit {t,f} via antennas and received via N_{R} receiving antennas, n_{t,f} denotes additive white noises, wherein it can be assumed that additive white noise in each of the time-frequency units is independent, with the bilateral noise power spectral density or variance being N₀.

Since the vectors rₜ_{₂}_{,f}_{₁} and rₜ_{₂}_{,f}_{₂} received in time-frequency units {t₂,f₁} and {t₂,f₂} are redundancies for the vectors rₜ_{₁}_{,f}_{₁} and rₜ_{₁}_{,f}₂_{₂} received in time-frequency units {t₁,f₁} and {t₁,f₂}, the redundant receiving vectors can be combined according to the following equations respectively:

$$\begin{matrix}{r}_{{t}_{1} , {f}_{1} + {f}_{2} , {f}_{1}} = \frac{{r}_{{t}_{1} , {f}_{1}} + {r}_{{t}_{2} , {f}_{1}}}{2} = H \cdot {[ {x}_{1} , {x}_{2} , {x}_{3} ]}^{T} + \frac{{n}_{{t}_{1} , {f}_{1}} + {n}_{{t}_{2} , {f}_{1}}}{2} & ( 3 ) \\ {r}_{{t}_{1} , {f}_{2} + {t}_{2} , {f}_{2}} = \frac{{r}_{{t}_{1} , {f}_{2}} + {r}_{{t}_{2} , {f}_{2}}}{2} = H \cdot {[ - {x}_{2}^{*} , {x}_{1}^{*} , 0 ]}^{T} + \frac{{n}_{{t}_{1} , {f}_{2}} + {n}_{{t}_{2} , {f}_{2}}}{2} & ( 4 )\end{matrix}$$

where rₜ_{₁}_{,f}_{₁}₊ₜ_{₂}_{,f}_{₁} and rₜ_{₁}_{,f}_{₂}₊ₜ_{₂}_{, f}_{₂} denote the vectors obtained through combination of rₜ_{₁}_{,f}_{₁} with rₜ_{₂}_{,f}_{₁} and rₜ_{₁}_{,f}_{₂} with rₜ_{₂}_{,f}_{₂} respectively. It's obvious that the variance of the additive white noise after combination is half of that before combination, that is, N₀/2.

The channel element vectors obtained through the combination and other channel elements extracted among the receiving signals form transmission code word vectors corresponding to the input symbols {x₁,x₂,x₃}, and equation (2) is updated as:

$${[ \begin{matrix}{r}_{{t}_{1} , {f}_{1} + {t}_{2} , {f}_{1}}^{T} \\ {r}_{{t}_{1} , {f}_{2} + {t}_{2} , {f}_{2}}^{T} \\ {r}_{{t}_{1} , {f}_{3}}^{T} \\ {r}_{{t}_{1} , {f}_{4}}^{T}\end{matrix} ]}^{T} = {[ \begin{matrix}{h}_{1}^{T} \\ {h}_{2}^{T} \\ {h}_{3}^{T}\end{matrix} ]}^{T} \cdot [ \begin{matrix}{x}_{1} & - {x}_{2}^{*} & {x}_{3}^{*} & 0 \\ {x}_{2} & {x}_{1}^{*} & 0 & {x}_{3}^{*} \\ {x}_{3} & 0 & - {x}_{1}^{*} & - {x}_{2}^{*}\end{matrix} ] + {[ \begin{matrix}{n}_{{t}_{1} , {f}_{1} + {t}_{2} , {f}_{1}}^{T} \\ {n}_{{t}_{1} , {f}_{2} + {t}_{2} , {f}_{2}}^{T} \\ {n}_{{t}_{1} , {f}_{3}}^{T} \\ {n}_{{t}_{1} , {f}_{4}}^{T}\end{matrix} ]}^{T} \qquad ( 5 )$$

where nₜ_{₁}_{,f}_{₁}₊ₜ_{₂}_{,f}_{₁} and nₜ_{₁}_{,f}_{₂}₊ₜ_{₂}_{,f}_{₂} denote additive noises after combination respectively. It can be seen from the equation that, the updated signal pattern is similar to the signal pattern obtained through coding with simple B₃^{′}-STBC mode. Therefore, the received channel elements can be decoded with a conventional linear combination method to recover the corresponding input symbols (specifically see the reference document).

Compared with the decoding method corresponding to the B₃^{′}-STBC mode, the variance of the additive white noise included in the updated channel element vectors in the signal pattern shown in equation (5) is half of that before the combination. By the separation of a linear filter, the SNR for the resulting input symbols can be expressed as:

$$\begin{matrix}S N {R}_{{x}_{1}} = \frac{{{E}_{s} ( {\vert {h}_{1} \vert}^{2} + {\vert {h}_{2} \vert}^{2} + {\vert {h}_{3} \vert}^{2} )}^{2}}{{N}_{0} ( {\vert {h}_{1} \vert}^{2} / 2 + {\vert {h}_{2} \vert}^{2} / 2 + {\vert {h}_{3} \vert}^{2} )} & ( 6 \text{-} 1 ) \\ S N {R}_{{x}_{2}} = \frac{{{E}_{s} ( {\vert {h}_{1} \vert}^{2} + {\vert {h}_{2} \vert}^{2} + {\vert {h}_{3} \vert}^{2} )}^{2}}{{N}_{0} ( {\vert {h}_{1} \vert}^{2} / 2 + {\vert {h}_{2} \vert}^{2} / 2 + {\vert {h}_{3} \vert}^{2} )} & ( 6 \text{-} 2 ) \\ S N {R}_{{x}_{3}} = \frac{{{E}_{s} ( {\vert {h}_{1} \vert}^{2} + {\vert {h}_{2} \vert}^{2} + {\vert {h}_{3} \vert}^{2} )}^{2}}{{N}_{0} ( {\vert {h}_{1} \vert}^{2} + {\vert {h}_{2} \vert}^{2} + {\vert {h}_{3} \vert}^{2} / 2 )} & ( 6 \text{-} 3 )\end{matrix}$$

while the conventional decoding method corresponding to the B₃^{′}-STBC mode will obtain an SNR given by:

$$S N R = S N {R}_{{x}_{2}} = \frac{{{E}_{s} ( {\vert {h}_{1} \vert}^{2} + {\vert {h}_{2} \vert}^{2} + {\vert {h}_{3} \vert}^{2} )}^{2}}{{N}_{0}} \qquad ( 7 )$$

By comparing equations (6-1), (6-2), (6-3) with equation (7), it can be found that the decoding method provided in the invention is able to achieve a higher SNR, and in turn to enhance the reception quality for the overall transmission data.

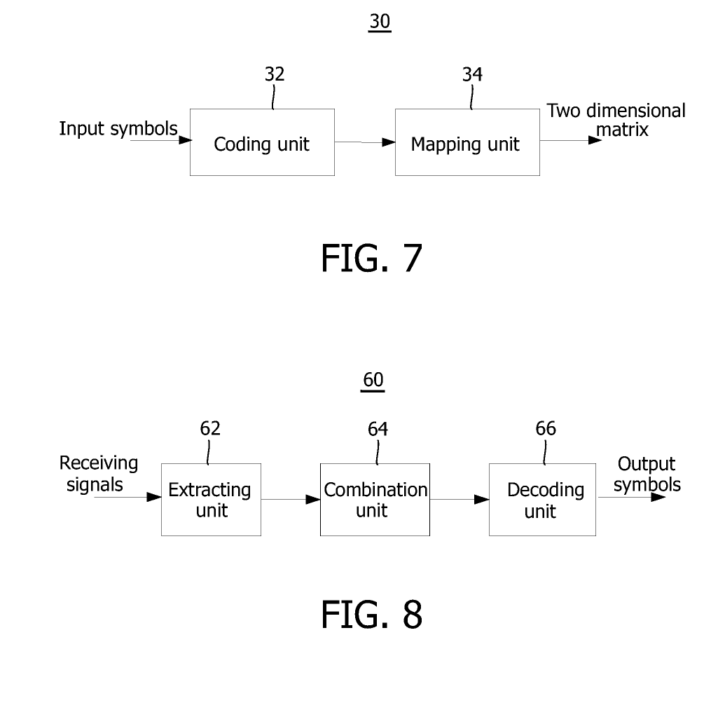

The space-time-frequency encoding method described above in connection with FIGS. 1-5 and the decoding method described above in connection with FIG. 6 can be implemented in software, hardware, or in combination of both. FIG. 7 is a block diagram illustrating an encoding apparatus 30 according to the invention. The encoding apparatus 30 comprises a coding unit 32 and a mapping unit 34.

The coding unit 32 is configured to code a set of transmission symbols according to a predetermined orthogonal STBC rule, as so to obtain a plurality of corresponding code words. A set of transmission symbols is coded according to a predetermined orthogonal STBC rule, as so to obtain a plurality of corresponding code words. Wherein the predetermined orthogonal STBC rule is known, and varies with the number of transmitting antennas. The basic principle for coding is to make the code words obtained through coding orthogonal to each other.

The coding unit is configured to generate the code words as shown in FIG. 2(a) with the Alamouti STBC mode for two transmitting antennas. In the case of two transmitting antennas, the coding unit is configured to code the input symbols or the symbol block {x₁,x₂} with the Alamouti STBC mode, to generate the code words as shown in FIG. 2(a). In the case of three transmitting antennas, the coding unit is configured to code the input symbols or the symbol block {x₁,x₂,x₃} with the extended Alamouti STBC mode B₃^{′}-STBC, to generate the code words as shown in FIG. 2(b). In the case of four transmitting antennas, the coding unit is configured to code the input symbols or the symbol block {x₁,x₂,x₃} with the extended Alamouti STBC mode B₄^{′}-STBC, to generate the code words as shown in FIG. 2(c).

The mapping unit 34 is configured to map a plurality of elements in each of the code words obtained by the coding unit 32 and the redundancies of at least part of the elements, as channel elements, to a plurality of predetermined time-frequency units in each of a plurality of two dimensional time-frequency matrixes corresponding to that code word, so that the channel elements in each of the matrixes can be transmitted via an antenna corresponding to that matrix.

Wherein the channels elements as redundancies can be single-time redundancies for multiple elements, multiple-time redundancies for a single element, or multiple-time redundancies for multiple elements. At the receiving side, elements in a code word can be combined with the redundancies for the elements, so as to enhance the SNR for this part of code word elements, and in turn to enhance the reception quality for the overall code word.

FIG. 8 is a block diagram illustrating a decoding apparatus 60 according to the invention. The decoding apparatus 60 comprises an extracting unit 62, a combination unit 64, and a decoding unit 66.

The extracting unit 62 is configured to extract a plurality of sets of faded channel elements as shown in equation (2) corresponding to a set of transmission symbols among a plurality of signal streams received from different transmitting antennas, wherein each of the sets of channel elements includes code word elements and redundant elements for at lest part of the code word elements.

The combination unit 64 is configured to combine the redundant elements in each of the sets of channel elements with the code word elements corresponding to the redundant elements, so that the channel elements obtained by the combination and the remaining code word elements in the set of channel elements make up of a transmission code word. The combination for redundant channel elements can be performed as shown in equations (3) and (4), or can be performed with weighting factors. The channel elements obtained after the combination and the remaining channel elements in the plurality of channel elements obtained by the extracting unit make up of a transmission code word corresponding to a set of transmission symbols. The signal pattern for the transmission code word can be expressed as that shown in equation (5). The signal pattern is similar to the conventional transmission code word corresponding to the B₃^{′}-STBC coding mode, with the only difference in that the combined elements in the transmission code word have a noise power spectral density half that before combination.

The decoding unit 66 is configured to perform linear combination on a plurality of transmission code words according to a predetermined orthogonal STBD rule, so as to recover a set of corresponding transmission symbols. The specific decoding rule for two transmitting antennas can be referred to the document: A simple transmit diversity technique for wireless communications, by S. Alamouti, IEEE J. on Select. Areas Commun., vol.16, (1998)10, 1451-1458. The specific decoding rule for three or four transmitting antennas can be referred to the reference document: Space-time block codes from orthogonal designs, by V. Tarokh, H. Jafarkhani, and A. R. Calderbank, IEEE Trans. on Info. Theory, vol.45, (1999)5, 1456-1467.

The encoding method and apparatus provided in the invention can be used in an OFDM system. In this case, before channel elements are output to a plurality of antennas for transmission, there generally comprises a step of transforming a plurality of channel elements corresponding to respective symbol intervals in the time-frequency matrixes from the frequency domain to the time domain with Fourier Inverse Transformation. While at the receiving side, the channel elements are transformed from the time domain to the frequency domain with Fourier Transformation, and then decoded.

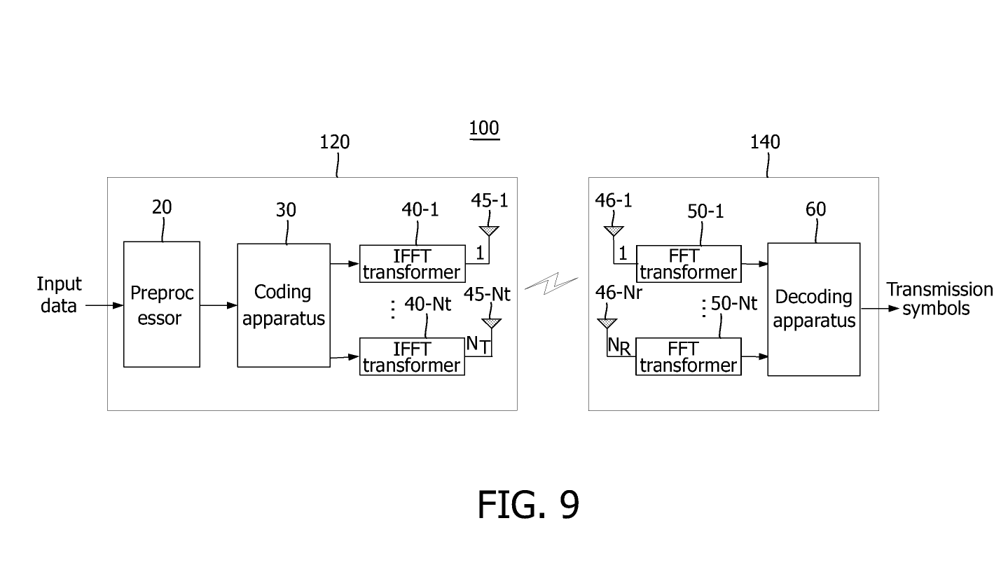

FIG. 9 is a block diagram illustrating an embodiment of a communication system 100 including an encoding apparatus 30 and a decoding apparatus 60 provided in the invention. The communication system 100 comprises a transmitter 120 and a receiver 140. The transmitter 120 further comprises a preprocessor 20 configured to perform channel coding and mapping on input data, a coding module 30 configured to obtain a plurality of time-frequency matrixes corresponding to antennas, at least one Fourier inverse transformer 40 configured to transform a plurality of channel elements corresponding to the respective symbol intervals in the time-frequency matrixes from the frequency domain to the time domain, and a plurality of antennas 45, the number of which is equal to that of the time-frequency matrixes, configured to transmit channel elements in different time-frequency matrixes via different space channels. The receiver 140 comprises at least one receiving antenna 46 configured to receive the corresponding transmission channel elements, at least one Fourier transformer 50 configured to transform the channel elements from the time domain to the frequency domain, and an above-mentioned decoding apparatus 60 configured to decode the channel elements, in order to recover the corresponding transmission symbols.

It is to be understood by those skilled in the art that the embodiments described herein are intended to illustrate, but not to limit the invention. Various improvements and modifications can be made to the space-time-frequency encoding method and apparatus for wireless communication system as disclosed in the present invention without departing from the spirit and scope of the present invention. The scope of the present invention is to be defined by the attached claims herein.

1. A space-time-frequency encoding method, comprising steps of:
(a) coding a set of transmission symbol according to a predetermined orthogonal space-time block coding rule, so as to obtain a plurality of code words; and
(b) mapping a plurality of elements in each of the plurality of code words and at least partial redundancies thereof, as channel elements, to a plurality of predetermined time-frequency units in one of a plurality of two dimensional time-frequency matrixes corresponding to the code word, so that the channel elements in each of the matrixes can be transmitted via an antenna corresponding to the matrix.

2. The method as claimed in claim 1, wherein the predetermined orthogonal space-time block coding rule in step (a) is an Alamouti space-time block coding rule for two transmitting antennas.

3. The method as claimed in claim 2, wherein the channel elements occupy three of four time-frequency units determined by two predetermined time units and two predetermined frequency units in the matrix, and wireless channels corresponding to the three time-frequency units undergo the same channel response.

4. The method as claimed in claim 2, wherein the channel elements occupy three time-frequency units determined by three predetermined time units and one frequency unit or by one time unit and three predetermined frequency units in the matrix.

5. The method as claimed in claim 1, wherein the predetermined orthogonal space-time block coding rule in step (a) is an extended Alamouti space-time block coding rule for three or four transmitting antennas.

6. The method as claimed in claim 5, wherein the channel elements occupy at least five of eight time-frequency units determined by two predetermined time units and four predetermined frequency units or by four predetermined time units and two predetermined frequency units in the matrix.

7. The method as claimed in claim 1, when the input symbols form a symbol block, each of the time-frequency units is made up of a plurality of sub-carriers and symbol intervals, and the number of symbols included in a symbol block is equal to the product of the number of the sub-carriers and the number of the symbol intervals included in one of the time-frequency units.

8. A decoding method, comprises steps of:
(a) extracting a plurality of sets of faded channel elements corresponding to a set of transmission symbols among a plurality of signal streams received from different transmitting antennas, wherein each of the sets of channel elements includes code word elements and at least partial redundancies thereof;
(b) combining the redundant channel elements and code word elements corresponding to the redundant channel elements in each of the sets of channel elements, so as to obtain a transmission code word composed of the channel elements obtained through the combination and the remaining code word elements in the set of channel elements; and
(c) performing a linear combination on a plurality of transmission code words according to a predetermined orthogonal space-time block decoding rule, so as to recover a set of transmission symbols.

9. The method as claimed in claim 8, wherein the predetermined orthogonal
space-time block decoding rule is an Alamouti space-time block decoding rule for two transmitting antennas.

10. The method as claimed in claim 8, wherein the predetermined orthogonal space-time block decoding rule is an extended Alamouti space-time block decoding rule for three or four transmitting antennas.

11. An encoding apparatus, comprising:
a coding unit, configured to code a set of transmission symbol sequences according to a predetermined orthogonal space-time block coding rule, so as to obtain a plurality of code words; and
a mapping unit, configured to map a plurality of elements in each of the plurality of code words and redundancy for at least part of the plurality of elements, as channel elements, to a plurality of predetermined time-frequency units in one of a plurality of two dimensional time-frequency matrixes corresponding to the code word, so that the channel elements in each of the matrixes can be transmitted via an antenna corresponding to the matrix;
wherein the predetermined orthogonal space-time block coding rule is one of an Alamouti space-time block coding for two transmitting antennas, an extended Alamouti space-time block coding for three transmitting antennas, and an expanded Alamouti space-time block coding for four transmitting antennas.

12. A decoding apparatus, comprising:
an extracting unit, configured to extract a plurality of sets of faded channel elements corresponding to a set of transmission symbols among a plurality of signal streams received from different transmitting antennas, wherein each the sets of channel elements includes code word elements and redundant elements for at least part of the code word elements;
a combination unit, configured to combine the redundant channel elements and code word elements corresponding to the redundant channel elements in each of the sets of channel elements, so as to obtain a transmission code word composed of the channel elements obtained through the combination and the remaining code word elements in the set of channel elements; and
a decoding unit, configured to perform a linear combination on a plurality of transmission code words according to a predetermined orthogonal space-time block decoding rule, so as to recover a set of transmission symbols; wherein the predetermined orthogonal space-time block decoding rule is one of an Alamouti space-time block decoding rule for two transmitting antennas, an extended Alamouti space-time block decoding for three transmitting antennas, and an extended Alamouti space-time block decoding for four transmitting antennas.

13. A wireless communication system comprising a transmitter and a receiver, wherein the transmitter comprises an encoding apparatus as claimed in claim 11, and the receiver comprises a decoding apparatus, comprising:
an extracting unit, configured to extract a plurality of sets of faded channel elements corresponding to a set of transmission symbols among a plurality of signal streams received from different transmitting antennas, wherein each the sets of channel elements includes code word elements and redundant elements for at least part of the code word elements;
a combination unit, configured to combine the redundant channel elements and code word elements corresponding to the redundant channel elements in each of the sets of channel elements, so as to obtain a transmission code word composed of the channel elements obtained through the combination and the remaining code word elements in the set of channel elements; and
a decoding unit, configured to perform a linear combination on a plurality of transmission code words according to a predetermined orthogonal space-time block decoding rule, so as to recover a set of transmission symbols; wherein the predetermined orthogonal space-time block decoding rule is one of an Alamouti space-time block decoding rule for two transmitting antennas, an extended Alamouti space-time block decoding for three transmitting antennas, and an extended Alamouti space-time block decoding for four transmitting antennas.
